(19) United States
(12) Patent Application Publication
(10) Pub. No.: US 2008/0166502 A1
(43) Pub. Date: Jul. 10, 2008

(54) Metal film pattern forming method

(75) Inventor: Kazuo Nakamae, Yokohama-shi (JP)

Correspondence Address: VENABLE LLP, P.O. BOX 34385, WASHINGTON, DC, 20043-9998, US

(73) Assignee: Sumitomo Electric Industries, Ltd., Osaka (JP)

(21) Appl. No.: 12/007,386

(22) Filed: Jan. 9, 2008

(30) Foreign Application Priority Data
Jan. 10, 2007 (JP) P2007-002596

(51) Int. Cl. C23C 14/04

(52) U.S. Cl. 427/597

(57) ABSTRACT

The present invention relates to a metal film pattern forming method by which a metal film pattern can be formed easily on a substrate. In the method, a metal film is caused to adhere to the surface of a substrate comprised of an insulating material having heat resistant properties. By illuminating a laser beam on the metal film on the substrate directly or via a glass plate, abrasion is caused on a portion of the metal film that is illuminated with the laser beam. A substrate having a metal film pattern adhered to the surface thereof is obtained through the abrasion by separating the metal film from the substrate surface after the illumination of the laser.

### BACKGROUND OF THE INVENTION

1. Field of the Invention

The present invention relates to a metal film pattern forming method of forming a metal film pattern on a substrate surface.

2. Related Background Art

In the past times, the following Patent Documents 1 to 3 and Non-Patent Document 1 to 2 are known as examples of production technology for wiring substrates on which electronic components and the like are mounted.

In these documents, for example Patent Document 1 discloses a method of forming conductive circuits. Firstly, in the forming of this document, a metal coating process (formation of metal film) is performed in advance on the surface of a resin molding. The conductive circuit is formed by illuminating the formed metal film with a laser beam, and then by electroplating the metal film. On the other hand, Patent Document 2 discloses a transfer method for thin film elements. In the transfer method of this document, a separation layer is provided on the substrate and a thin film element such as a TFT is formed on the substrate. Afterwards, peeling occurs when the separation layer is illuminated with a laser beam and thus the transfer is performed. Moreover, a repair method for disconnected locations is disclosed in Non-Patent Document 1. In the repair method of this document, a metal material for transfer formed on silica glass in advance is prepared. Disconnected locations are repaired by being illuminated with a laser beam in a state in which this metal material for transfer is placed on a disconnected wiring pattern.

[Patent Document 1] Japanese Patent Application Laid-Open No. H6-164105

[Patent Document 2] Japanese Patent Application Laid-Open No. H10-125931

[Patent-Document 3] Japanese Patent Application Laid-Open No. 2003-177229

[Non-Patent Document 1] “New Repair Technology for Liquid Crystal Panels: Inline Process through Increasing Speed by One Digit” (Nikkei Microdevice, July, 2006, p. 83)

[Non-Patent Document 2] “Principles of the LITI Method” (Nikkei Microdevice”, July, 2006, p. 47 and FIG. 9)

### SUMMARY OF THE INVENTION

The present inventors have examined the above prior art, and as a result, have discovered the following problems.

Namely, the methods described in the above documents respectively require a process for forming a metal film in advance on the substrate surface (see Patent Document 1), a process for forming a thin film element on a separation layer (see Patent Document 2), and a process for forming a metal material for transfer on silica glass (see Non-Patent Document 1). Thus, in the prior art, there is a problem in that the number of processes is increased, leading to an increase in production costs.

The present invention has been developed to eliminate the problems described above. It is an object of the present invention to provide a metal film pattern forming method in which a metal film pattern can be formed on a substrate surface easily and with low cost.

A metal film pattern forming method according to the present invention is a method of forming a metal film pattern, which can be employed as electrical wiring or the like, on a substrate surface, and comprises a metal film placement process, a laser illumination process, and a separation process for the placed metal film. In the metal film placement process, a metal film is placed on the surface of the substrate in a state in which the metal film directly contacts the substrate. In the laser illumination process, a laser beam is illuminated on the metal film from the side opposite to the substrate side thereof. At a portion of the metal film placed on the substrate that is illuminated with the laser beam, abrasion (laser abrasion) is caused by a laser beam. Note that laser abrasion refers to the phenomenon of material in the region of laser illumination dissolving, evaporating and disappearing due to the absorption of heat caused by the laser illumination at the time the laser beam illuminates the material. Moreover, in the separation process, the remaining of metal film no longer needed, excluding the metal film pattern formed through the laser abrasion and adhered on the substrate, is separated from the surface of the substrate. Through the above processes, a metal film pattern conforming to the laser illumination pattern is formed on the substrate surface. In this manner, extremely simple processes are performed using this metal film pattern forming method, and a metal film pattern can be easily formed on the substrate surface. Complicated processes are rendered unnecessary, thus production costs are effectively suppressed.

In the metal film pattern forming method according to the present invention, in the laser illumination process, it is preferable for a glass plate to be placed on the metal film so as to sandwich the metal film together with the substrate prior to the illumination of the laser. In the laser illumination process, the laser beam is illuminated on the entire metal film via the glass plate placed in this manner. By placing the glass plate on the metal film, the adherence of the substrate and the metal film can be increased, and variations in the relative positions of the substrate and the metal film are effectively suppressed. Furthermore, the reliability of the quality of the metal film pattern adhered to the substrate surface using laser abrasion is improved. Note that the glass plate which is placed temporarily on the metal film is removed after the illumination of the laser.

In the metal film pattern forming method according to the present invention, it is preferable for the substrate to be comprised of an insulating material having heat resistant properties. The reason for this is that various applications such as electrical wiring substrates can be conceived. Moreover, by employing a substrate comprised of heat resistant material, the influence of the heat on the substrate when the laser beam is illuminated is reduced, and thus the reliability of the quality of the metal film pattern formed on the surface is improved. Furthermore, electrical conduction between the metal film pattern, serving as electrical wiring, on the substrate and the outside is prevented, and thus electrical losses are effectively suppressed.

In the metal film pattern forming method according to the present invention, it is preferable to further comprise a sheet placement process to be performed after the separation process. In this sheet placement process, a sheet, which is comprised of an insulating material having heat resistant properties, is joined to the surface of the substrate to which the metal film pattern is adhered through the laser abrasion, after the metal film is separated from the surface of the substrate. In this case, a multilayer wiring substrate can be easily produced. Moreover, after the metal film pattern is formed on the substrate surface, the residual metal film is collected, and is recycled, thus it is possible to further reduce production costs.

The present invention will be more fully understood from the detailed description given hereinbelow and the accompanying drawings, which are given by way of illustration only and are not to be considered as limiting the present invention.

Further scope of applicability of the present invention will become apparent from the detailed description given hereinafter. However, it should be understood that the detailed description and specific examples, while indicating preferred embodiments of the invention, are given by way of illustration only, since various changes and modifications within the scope of the invention will be apparent to those skilled in the art from this detailed description.

### BRIEF DESCRIPTION OF THE DRAWINGS

FIG. 1A is a perspective view for explaining a representative method of placing a metal film on a substrate surface, and FIG. 1B is a cross sectional view of the substrate portion along the I-I line in FIG. 1A;

FIGS. 2A to 2D are views for explaining each process in a first embodiment of a metal film pattern forming method according to the present invention; and

FIGS. 3A to 3D are views for explaining each process in a second embodiment of the metal film pattern forming method according to the present invention.

### DESCRIPTION OF THE PREFERRED EMBODIMENTS

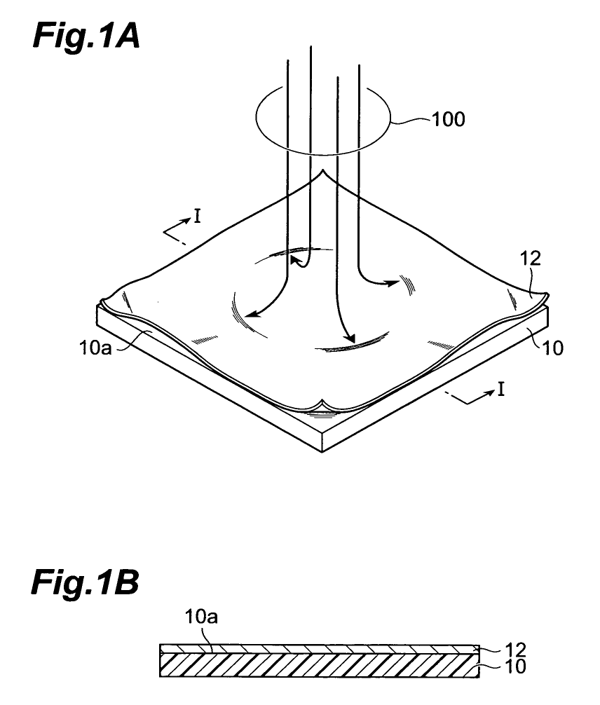

In the following, embodiments of a metal film pattern forming method according to the present invention will be explained in detail with reference to FIG. 1A to 3D. In the description of the drawings, identical or corresponding components are designated by the same reference numerals, and overlapping description is omitted.

First, an explanation will be given of a representative method of placing a metal film on a substrate surface. FIG. 1A is a perspective view for explaining a representative method of placing a metal film 12 on the top surface of a substrate 10. Moreover, FIG. 1B is a cross sectional view of the substrate 10 along the I-I line in FIG. 1A.

As shown in FIG. 1A, the prepared substrate 10 is a resin plate with two flat surfaces opposing each other, and the metal film 12 is placed on the substrate 10. At this time, in order to cause the metal film 12 to adhere to the surface 10a of the substrate 10, air 100 is blown towards the metal film 12 placed on the substrate 10. The metal film 12 is a metal thin film with approximately 10 μm and thus very difficult to handle, however, it is possible to easily cause the metal film 12 to adhere to the surface 10a of the substrate 10 by blowing air. In this manner, the substrate 10 and the metal film 12 are adhered together as shown in FIG. 1B.

Note that when the metal film 12 is only simply placed on the surface 10a of the substrate 10, cases can be conceived in which misalignment and the lack of ability to eliminate gaps between the metal film 12 and the substrate 10 occur due to irregular air flow. Therefore, after the metal film 12 is placed on the surface 10a of the substrate 10, it is preferable to further place transparent glass on the metal film 12. In this manner, through the placement of the transparent glass, the relative misalignment of the metal film 12 and the substrate 10 is prevented, and it is possible to eliminate the gaps between the metal film 12 and the substrate 10. In the below first and second embodiments, a state in which transparent glass is used to press the metal film 12 to the substrate 10 is shown.

### First Embodiment

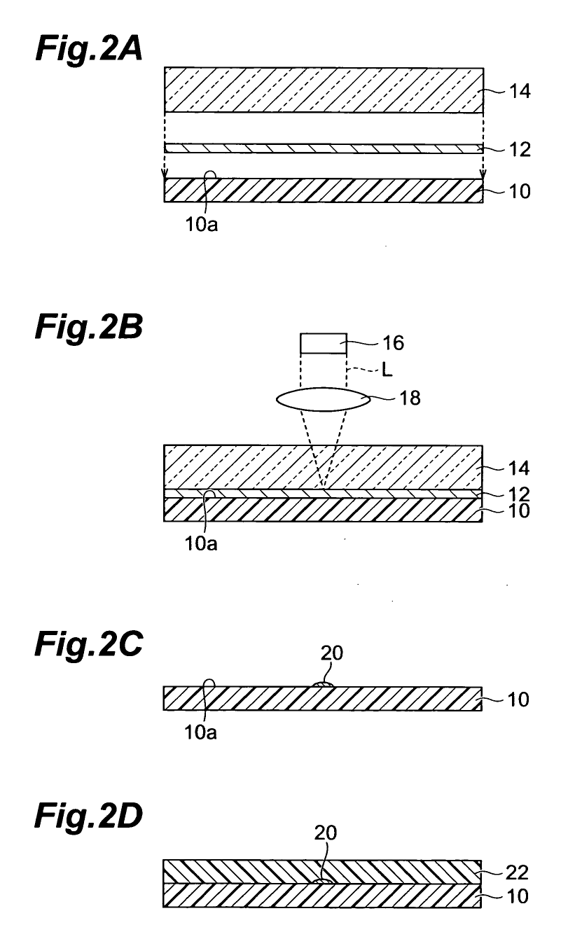

FIGS. 2A to 2D are views for explaining each process in the first embodiment of the metal film pattern formation process according to the present invention. In the first embodiment, a metal film pattern 20 is formed on the surface 10a of the substrate 10.

First, the substrate 10 is prepared. Here, the prepared substrate 10 is a polyimide resin plate with two flat surfaces opposing each other, having a thickness of 50 μm. Polyimide resin has superior electrical insulating and heat resistant properties, thus electrical conduction between the electrical wiring (metal film pattern) of the substrate 10 and the outside is prevented. Thus, electrical loss can be prevented and the influence the heat absorption of the substrate 10 when a laser beam is illuminated on the substrate 10 is reduced. As a result, the reliability of the quality of the formed metal film pattern 20 is improved.

Subsequently, the metal film 12 is placed on the surface 10a of the substrate 10. The metal film 12 is comprised of copper and processed to a thickness of 10 μm. The transparent glass 14 is placed on the metal film 12 in a manner such that corrugation does not form on the metal film 12, and in this manner, the metal film 12 and the substrate 10 adhere to each other (see FIG. 2A).

Next, a laser head 16 and an object of illumination (the substrate 10) are aligned. When the alignment process is finished, a laser beam L illuminates the metal film 12 via a focusing lens 18 from above the transparent glass 14. Here, the employed laser beam source is a YAG laser with a wavelength of 1.06 μm, a pulse width of 10 nm and an average output of five watts (see FIG. 2B). Also, the focal distance of the focusing lens 18 is 50 mm. On the other hand, the space between the focusing lens 18 and the metal film 12 is adjusted so that the focal point of the laser beam L, which is focused by the focusing lens 18, is on the surface of the metal film 12. A portion of the metal film 12 (the region illuminated with the laser beam L), has abrasion performed thereon through the illumination of the laser beam L. The metal film pattern 20 is caused to adhere to the surface 10a of the substrate 10 through such laser abrasion (the metal film pattern 20 is formed).

The illumination of the laser beam L is performed as appropriate using a galvano scanner system. In this case, illumination of the laser beam L can be performed freely, and the metal film pattern 20, which becomes the metal wiring, can be easily formed.

After forming the metal film pattern 20, the transparent glass 14 is removed and then the residual metal film 12 (the remaining of metal film) is further removed (see FIG. 2C). Subsequently, a sheet 22 is placed on the substrate 10 so as to sandwich the metal film pattern 20 which is adhered to the surface 10a of the substrate 10. The substrate 10 and the sheet 22 are joined to each other by the illumination of the laser beam L. Note that in this case the substrate 10 and the sheet 22 may also be joined using an adhesive in place of the illumination of the laser beam L. The sheet 22, in the same manner as the substrate 10, is comprised of a polyimide resin and is processed to have a width identical to the substrate 10. In this manner, an electrical wiring substrate is realized having a metal film pattern 20 formed between the substrate 10 and the sheet 22 (see FIG. 2D).

In the above first embodiment, the metal film 12 is directly placed on the surface 10a of the substrate 10, and the laser beam L is illuminated on the metal film 12. Moreover, the illumination of the laser beam L causes abrasion on a portion of the metal film 12, and the metal film pattern 20 adheres on the surface 10a of the substrate 10 at the positions of the laser illumination. In this manner the first embodiment can easily form a metal film pattern 20 on the surface 10a of the substrate 10 using a simple process. Furthermore, the metal film pattern forming method according to the first embodiment does not require complicated processing as in the prior art (a portion (metal film pattern 20) of the metal film 12 is formed on the surface 10a of the substrate 10 by the illumination of the laser beam L), thus production costs can be effectively suppressed.

Additionally, in the first embodiment, the transparent glass 14 is used to adhere the substrate 10 and the metal film 12, and thus the reliability of the quality of the formed metal film pattern 20 can be improved. After the illumination of the laser beam L, the residual metal film 12 (the remaining of metal film) is removed, and the sheet 22 is further placed on the substrate 10 so as to sandwich the formed metal film pattern 20. By joining the substrate 10 and the sheet 22 a two layer wiring can be easily manufactured. Moreover, after the metal film pattern 20 is formed, the residual metal film 12 is collected, and is recycled, thus production costs are further reduced.

### Second Embodiment

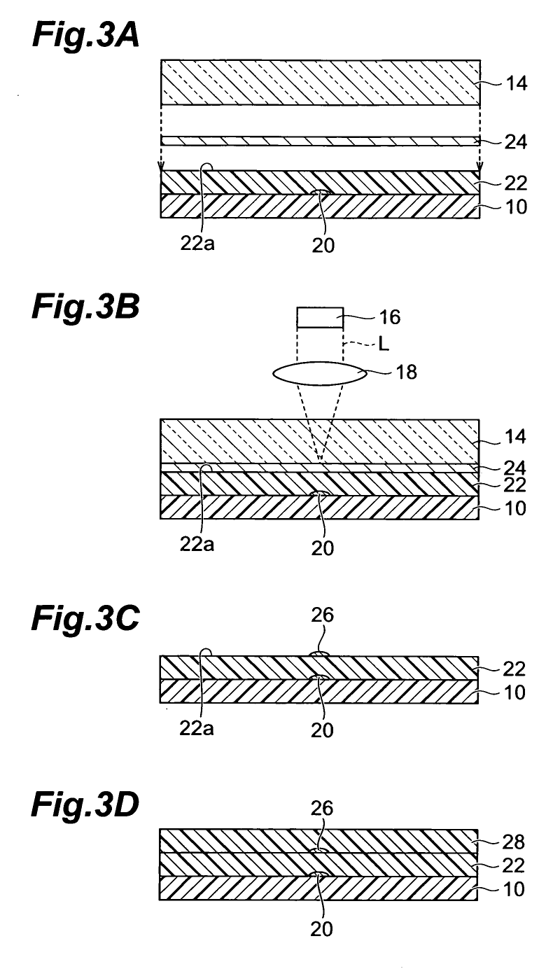

In the following, with reference to FIGS. 3A to 3D, a second embodiment of the metal film pattern forming method according to the present invention will be explained. FIGS. 3A to 3D are views for explaining each process in the second embodiment of the metal film pattern formation process according to the present invention.

First, in the same manner as in the first embodiment, electrical wiring (the metal film pattern 20) is manufactured which is masked by the substrate 10 and the sheet 22. Next, a second metal film 24 is placed on the surface 22a of the sheet 22. The transparent glass 14 is placed on the metal film 24 in a manner such that corrugation does not form on the metal film 24, and in this manner, the metal film 24 and the sheet 22 adhere to each other (see FIG. 3A). The metal film 24, in the same manner as the metal film 12, is comprised of copper, and is processed to have a thickness identical to the metal film 12.

Next, the laser head 16 and the object of illumination (the substrate 10) are aligned. When the alignment process is finished, the laser beam L illuminates the metal film 24 via the focusing lens 18 from above the transparent glass 14 (see FIG. 3B). A portion of the metal film 24 (the region illuminated with the laser beam L), has abrasion performed thereon through the illumination of the laser beam L. A metal film pattern 26 is adhered to the surface 22a of the sheet 22 through such laser abrasion (the metal film pattern 26 is formed). Note that the illumination of the laser beam L is performed as appropriate using a galvano scanner system.

After forming the metal film pattern 26, the transparent glass 14 is removed and then the residual metal film 24 (the remaining of metal film) is further removed (see FIG. 3C). Subsequently, a sheet 28 is placed on the sheet 22 so as to sandwich the formed metal film pattern 26, and the sheet 22 and the sheet 28 are joined to each other by the illumination of the laser beam L. Note that the sheet 28, in the same manner as the substrate 10, is comprised of a polyimide resin and is processed to have a width identical to the substrate 10. In this manner, an electrical wiring substrate is realized having metal film patterns 20 and 26 formed between the substrate 10 and the sheets 22 and 28 (see FIG. 3D).

When the above processes are repeated an electrical wiring substrate having a plurality of layers can be easily manufactured. Such a metal film pattern forming method for a plurality of layers would have the same effects as the metal film pattern forming method according to the above second embodiment, thus a redundant explanation is omitted.

The metal film pattern forming method according to the present invention is not limited to the above embodiments. For example, a YAG laser has been applied as the light source for the laser beam L, however, a CO₂ laser, a fiber laser, or the like may also be applied. Moreover, the material for the substrate 10 and the sheets 22 and 28 is not limited to the polyimide resin but may be another material, such as PET (polyethylene terephthalate), having electrical insulating and heat resistant properties.

As described above, the present invention can provide a metal film pattern forming method which is simple and enables a reduction in cost.

From the invention thus described, it will be obvious that the embodiments of the invention may be varied in many ways. Such variations are not to be regarded as a departure from the scope of the invention, and all such modifications as would be obvious to one skilled in the art are intended for inclusion within the scope of the following claims.

What is claimed is:

1. A metal film pattern forming method of forming a metal film pattern on a surface of a substrate, comprising the steps of:
placing a metal film on the surface of said substrate in a state in which said metal film directly contacts said substrate;
causing abrasion on a portion of said metal film that is illuminated with a laser beam, by illuminating the laser beam on said metal film from the side opposite to the substrate side thereof; and
separating the remaining of said metal film, excluding a metal film pattern formed through the abrasion and adhered on said substrate, from the surface of said substrate.

2. A metal film pattern forming method according to claim 1, wherein a glass plate is placed on said metal film so as to sandwich said metal film together with said substrate, prior to the illumination of the laser, and
wherein said glass plate placed on said metal film is removed after the illumination of the laser.

3. A metal film pattern forming method according to claim 1, wherein said substrate is comprised of an insulating material having heat resistant properties.

4. A metal film pattern forming method according to claim 1, wherein a sheet, which is comprised of an insulating material having heat resistant properties, is joined to the surface of said substrate to which said metal film pattern is adhered through the abrasion, after said metal film is separated from the surface of said substrate.
